(19) United States
(12) Patent Application Publication
(10) Pub. No.: US 2025/0241091 A1
(43) Pub. Date: Jul. 24, 2025

(54) LIGHT EMITTING ELEMENT AND DISPLAY DEVICE COMPRISING THE SAME

(71) Applicant: LG Display Co., Ltd., Seoul (KR)

(72) Inventors: Kiyong YANG, Seoul (KR); SeungJun LEE, Paju-si (KR); YongSeok KWAK, Paju-si (KR)

(73) Assignee: LG Display Co., Ltd., Seoul (KR)

(21) Appl. No.: 18/793,637

(22) Filed: Aug. 2, 2024

(30) Foreign Application Priority Data
Jan. 24, 2024 (KR) 10-2024-0011191

(51) Int. Cl. H01L 33/38; H01L 25/16; H01L 33/54; H01L 33/62

(52) U.S. Cl. CPC H10H 20/8312; H01L 25/167; H10H 20/853; H10H 20/857

(57) ABSTRACT

Discussed is a light emitting element. The light emitting element includes a first semiconductor layer, a light emitting layer disposed on the first semiconductor layer, a second semiconductor layer disposed on the light emitting layer, a first electrode disposed on the first semiconductor layer, a second electrode disposed on the second semiconductor layer, a first insulating layer disposed on the first electrode and the second electrode, and a polarization inducing layer disposed on the first insulating layer.

### CROSS-REFERENCE TO RELATED APPLICATIONS

This application claims priority to Korean Patent Application No. 10-2024-0011191 filed on Jan. 24, 2024, in the Korean Intellectual Property Office, the entire contents of which is hereby expressly incorporated by reference into the present application.

### BACKGROUND

### Field

The present disclosure relates to a light emitting element and a display device including the same, and more particularly, to a light emitting diode (LED) and a display device using the same.

### Discussion of the Related Art

Nowadays, there are various display devices that are used for a monitor of a computer, a television, a cellular phone, or the like. Among such display devices, there are an organic light emitting display (OLED) device which is a self-emitting device, a liquid crystal display (LCD) device which requires a separate light source, and the like.

The display device can be further used in personal digital assistants as well as monitors of computers and televisions and a display device with a large display area and a reduced volume and weight is being studied.

Further, recently, a display device including a light emitting diode (LED) is attracting attention as a next generation display device for various applications. Since the LED is formed of an inorganic material, rather than an organic material, reliability can be improved so that a lifespan thereof is longer than that of the liquid crystal display device or the organic light emitting display device, which are prone to failure from intrusion of moisture. Further, the LED has a fast-lighting speed, excellent luminous efficiency, and a stronger impact resistance so that a stability is excellent and an image having a high luminance can be displayed as compared to those of the liquid crystal display device or the organic light emitting display device.

### SUMMARY OF THE DISCLOSURE

An object to be achieved by the present disclosure is to provide a light emitting element with an improved assembly rate, and a display device including the same.

Another object to be achieved by the present disclosure is to provide a light emitting element with a reduced number of manufacturing processes, and a display device including the same.

Still another object to be achieved by the present disclosure is to provide a light emitting element that is capable of connecting electrodes regardless of a rotating direction, and a display device including the same.

Still another object to be achieved by the present disclosure is to provide a light emitting element with high luminance, and a display device including the same.

Objects of the present disclosure are not limited to the above-mentioned objects, and other objects, which are not mentioned above, can be clearly understood by those skilled in the art from the following descriptions.

According to an aspect of the present disclosure, there is provided a light emitting element. The light emitting element comprises a first semiconductor layer, a light emitting layer disposed on the first semiconductor layer, a second semiconductor layer disposed on the light emitting layer, a first electrode disposed on the first semiconductor layer, a second electrode disposed on the second semiconductor layer, a first insulating layer disposed on the first electrode and the second electrode, and a polarization inducing layer disposed on the first insulating layer.

According to an aspect of the present disclosure, there is provided a display device. The display device comprises a substrate including a plurality of sub pixels, a plurality of light emitting elements disposed in the plurality of sub pixels on the substrate, a plurality of transistors disposed on the substrate, and a connection electrode connecting the plurality of transistors and the plurality of light emitting elements. Each of the plurality of light emitting elements includes a polarization inducing layer. The connection electrode is electrically connected to the plurality of light emitting elements on side surfaces of the plurality of light emitting elements.

Other detailed matters of the example embodiments are included in the detailed description and the drawings.

In the present disclosure, when assembling a light emitting element to a display panel, the light emitting element can be connected to the display panel even if the same rotates.

In the present disclosure, a top surface of an electrode of a light emitting element can be seated on an assembly substrate, thereby reducing manufacturing processes.

In the present disclosure, luminous efficiency of a light emitting element can be improved.

The effects according to the present disclosure are not limited to the contents exemplified above, and more various effects are included in the present disclosure.

### BRIEF DESCRIPTION OF THE DRAWINGS

The above and other aspects, features and other advantages of the present disclosure will be more clearly understood from the following detailed description taken in conjunction with the accompanying drawings, in which:

FIG. 1 is a perspective view schematically illustrating a light emitting element according to one example embodiment of the present disclosure;

FIG. 2 is a plan view illustrating a light emitting element according to one example embodiment of the present disclosure;

FIG. 3 is a cross-sectional view taken along the line A-A′ of FIG. 2;

FIGS. 4A and 4B are graphs for explaining effects of a light emitting element according to one example embodiment of the present disclosure;

FIG. 5 is a block diagram schematically illustrating a configuration of a display device according to one example embodiment of the present disclosure; and

FIG. 6 is a cross-sectional view illustrating a pixel area of a display device according to one example embodiment of the present disclosure.

### DETAILED DESCRIPTION OF THE EMBODIMENTS

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies can be omitted to avoid unnecessarily obscuring the subject matter of the present disclosure. The terms such as “including,” “having,” and “consist of” used herein are generally intended to allow other components to be added unless the terms are used with the term “only”. Any references to singular can include plural unless expressly stated otherwise.

Components are interpreted to include an ordinary error range even if not expressly stated.

When the position relation between two parts is described using the terms such as “on”, “above”, “below”, and “next”, one or more parts can be positioned between the two parts unless the terms are used with the term “immediately” or “directly”.

When an element or layer is disposed “on” another element or layer, another layer or another element can be interposed directly on the other element or therebetween.

Although the terms “first”, “second”, and the like are used for describing various components, these components are not confined by these terms. These terms are merely used for distinguishing one component from the other components. Therefore, a first component to be mentioned below can be a second component in a technical concept of the present disclosure.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

The term “can” fully encompasses all the meanings and coverages of the term “may.”

Hereinafter, a light emitting element and a display device according to example embodiments of the present disclosure will be described in detail with reference to accompanying drawings.

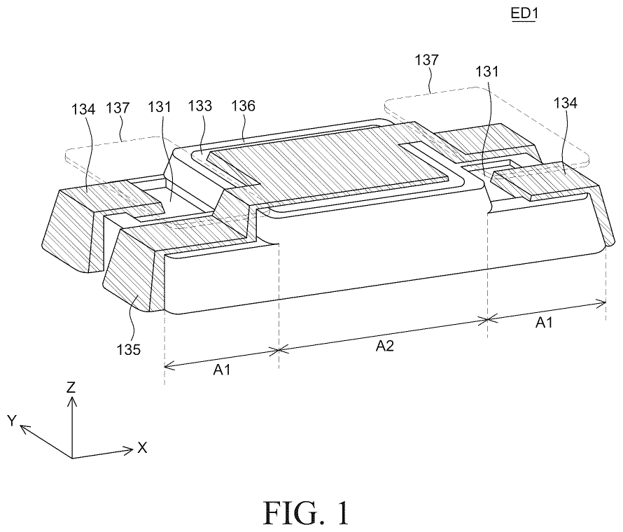

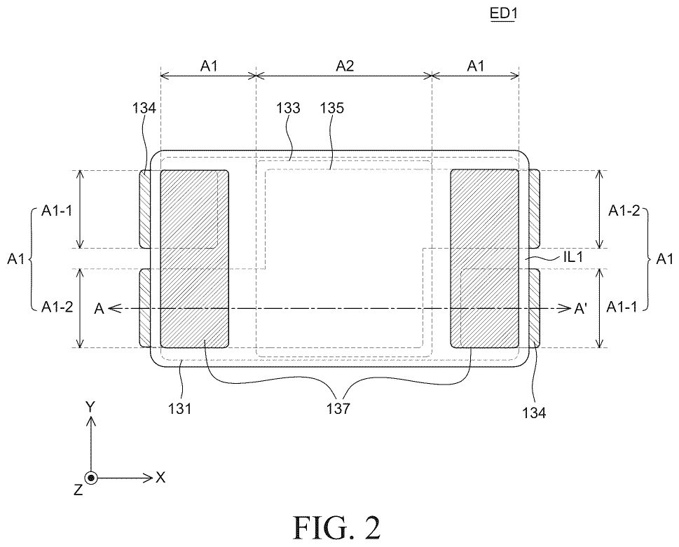

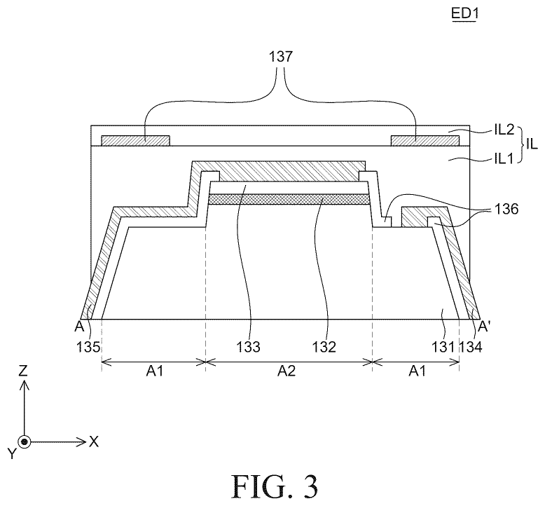

FIG. 1 is a cross-sectional view schematically illustrating a light emitting element according to one example embodiment of the present disclosure. FIG. 2 is a top view illustrating a light emitting element according to one example embodiment of the present disclosure. FIG. 3 is a cross-sectional view taken along the line A-A′ of FIG. 2. All components of each light emitting element according to all embodiments of the present disclosure are operatively coupled and configured.

In FIG. 1, for convenience of illustration, a polarization inducing layer 137 is shown as a dotted line, and a light emitting layer 132, a first insulating layer IL1, and a second insulating layer IL2 are omitted. In FIG. 2, for convenience of illustration, a light emitting layer 132, an encapsulation layer 136, and a second insulating layer IL2 are omitted.

Referring to FIGS. 1 to 3, a light emitting element ED1 can include a first semiconductor layer 131, a light emitting layer 132, a second semiconductor layer 133, a first electrode 134, a second electrode 135, an encapsulation layer 136, a plurality of insulating layers IL, and a polarization inducing layer 137. But aspects of the present disclosure are not limited thereto.

The light emitting element ED1 can be formed in various structures such as a lateral type, a vertical type, or a flip chip type. The lateral type light emitting element includes a first electrode and a second electrode that are horizontally (laterally) disposed on both sides of a light emitting layer. The vertical type light emitting element includes a first electrode and a second electrode that are disposed above and below a light emitting layer. The flip chip type light emitting element has substantially the same structure as the lateral type light emitting element. The lateral type light emitting element has the first electrode and the second electrode that are disposed laterally above the light emitting layer, whereas the flip chip type light emitting element has the first electrode and the second electrode that are laterally disposed below the light emitting layer. Hereinafter, a description will be made on the assumption that the light emitting element ED1 has a lateral structure, but the type of the light emitting element ED1 is not limited thereto.

The first semiconductor layer 131 can be disposed below the light emitting element ED1. The first semiconductor layer 131 can be a layer formed by doping a specific material with n-type and/or p-type impurities. But aspects of the present disclosure are not limited thereto. For example, the first semiconductor layer 131 can be a layer formed by doping a material, such as gallium nitride (GaN), indium aluminum phosphide (InAlP), or gallium arsenide (GaAs) with n-type and/or p-type impurities. Here, the p-type impurity can be magnesium, zinc (Zn), beryllium (Be), etc., and the n-type impurity can be silicon (Si), germanium, tin (Sn), etc., but are not limited thereto. In the present disclosure, the first semiconductor layer 131 can defined as an n-type semiconductor layer doped with the n-type impurity, but is not limited thereto.

The first semiconductor layer 131 can include a first area A1 that does not overlap the second semiconductor layer 133, and a second area A2 that overlaps the second semiconductor layer 133. But aspects of the present disclosure are not limited thereto. For example, the first area A1 of the first semiconductor layer 131 can externally protrude from the second semiconductor layer 133 and the light emitting layer 132 to be exposed from the second semiconductor layer 133 and the light emitting layer 132. The second area A2 of the first semiconductor layer 131 can overlap the second semiconductor layer 133 and the light emitting layer 132. As illustrated in FIG. 3, both ends of the first semiconductor layer 131 can be exposed from the second semiconductor layer 133 and the light emitting layer 132 in a major axis direction of the light emitting element ED1. Accordingly, the first area A1 can be disposed on both sides of the second area A2, but is not limited thereto. For example, in FIGS. 1 to 3, the first areas A1 are shown spaced apart from each other with the second area A2 interposed therebetween, but are not limited thereto, and the first area A1 can surround the second area A2.

Referring to FIG. 2, the first area A1 of the first semiconductor layer 131 can include a 1-1th area A1-1 and a 1-2th area A1-2. The 1-1th area A1-1 and the 1-2th area A1-2 can be disposed to extend from one surface of the second area A2, respectively. The 1-1th area A1-1 and the 1-2th area A1-2 can be disposed to be adjacent to each other.

The first semiconductor layer 131 can include a plurality of 1-1th areas A1-1 and a plurality of 1-2th areas A1-2. At this time, the plurality of 1-1th areas A1-1 can be disposed to face each other with respect to the center of the light emitting element ED1, and the plurality of 1-2th areas A1-2 can be disposed to face each other with respect to the center of the light emitting element ED1. Therefore, as illustrated in FIG. 2, the plurality of 1-1th areas A1-1 and the plurality of 1-2th areas A1-2 can be disposed alternately along a periphery of the second area A2. But aspects of the present disclosure are not limited thereto. For example, the 1-1th areas A1-1 can be disposed on an upper left portion and a lower right portion of the light emitting element ED1, and the 1-2th areas A1-2 can be disposed on a lower left portion and an upper right portion of the light emitting element ED1, but are not limited thereto.

Referring to FIG. 3, the light emitting layer 132 and the second semiconductor layer 133 can be disposed on the first semiconductor layer 131.

Referring to FIGS. 2 and 3, the light emitting layer 132 and the second semiconductor layer 133 can be disposed to overlap a portion of the first semiconductor layer 131. But aspects of the present disclosure are not limited thereto. For example, the light emitting layer 132 and the second semiconductor layer 133 can be disposed to overlap the second area A2 of the first semiconductor layer 131.

The light emitting layer 132 can emit light by receiving holes and electrons from the first semiconductor layer 131 and the second semiconductor layer 133. The light emitting layer 132 can have a single-layer or multi-quantum well (MQW) structure, and can be made of, for example, indium gallium nitride (InGaN) or gallium nitride (GaN), but is not limited thereto.

The second semiconductor layer 133 can be disposed on the light emitting layer 132. The second semiconductor layer 133 can be a layer formed by doping a specific material with n-type and p-type impurities. But aspects of the present disclosure are not limited thereto. For example, the second semiconductor layer 133 can be a layer formed by doping a material, such as gallium nitride (GaN), indium aluminum phosphide (InAlP), or gallium arsenide (GaAs) with n-type and p-type impurities. The p-type impurity can be magnesium, zinc (Zn), beryllium (Be), etc., and the n-type impurity can be silicon (Si), germanium, tin (Sn), etc., but are not limited thereto. In the present disclosure, the second semiconductor layer 133 can be defined as a p-type semiconductor layer doped with the p-type impurity, but is not limited thereto.

The encapsulation layer 136 can be disposed to surround at least portions of the first semiconductor layer 131, the light emitting layer 132, and the second semiconductor layer 133. The encapsulation layer 136 can protect the first semiconductor layer 131, the light emitting layer 132, and the second semiconductor layer 133.

The encapsulation layer 136 can cover top and side surfaces of the first semiconductor layer 131, the light emitting layer 132, and the second semiconductor layer 133.

The encapsulation layer 136 can cover the top surface of the first semiconductor layer 131 and the top surface of the second semiconductor layer 133 in areas excluding the area where the first electrode 134 and the second electrode 135 are disposed.

Referring to FIG. 1, the encapsulation layer 136 can be disposed to overlap a portion of the first area A1 so as to cover a portion of the top surface of the first semiconductor layer 131 and expose a top surface of the second insulating layer IL2 at another portion of the first area A1. But aspects of the present disclosure are not limited thereto. For example, the encapsulation layer 136 can expose the upper surface of the first semiconductor layer 131 in the 1-1th area A1-1 illustrated in FIG. 2, and cover the top surface of the first semiconductor layer 131 in the 1-2th area A1-2.

Meanwhile, the encapsulation layer 136 can cover a portion of the top surface of the second semiconductor layer 133 in the second area A2, but is not limited thereto. Alternatively, the encapsulation layer 136 can fully expose the top surface of the second semiconductor layer 133 in the second area A2.

The encapsulation layer 136 can cover side surfaces of the first semiconductor layer 131, the light emitting layer 132, and the second semiconductor layer 133. Accordingly, the encapsulation layer 136 can insulate the first semiconductor layer 131 from the first electrode 134 and the second electrode 135 on the side surfaces of the first semiconductor layer 131, and insulate the second semiconductor layer 133 from the second electrode 135 on the side surface of the second semiconductor layer 133.

Referring to FIGS. 1 to 3, the first electrode 134 and the second electrode 135 can be disposed above the encapsulation layer 136. The first electrode 134 can be disposed above the encapsulation layer 136 and the first semiconductor layer 131. The first semiconductor layer 131 can be a semiconductor layer doped with n-type impurities, and the first electrode 134 can be a cathode.

The first electrode 134 can be made of a conductive material, for example, an opaque conductive material such as titanium (Ti), gold (Au), silver (Ag), copper (Cu), or an alloy thereof, but is not limited thereto. For example, the first electrode 134 can be made of a transparent conductive material such as indium tin oxide ITO or indium zinc oxide IZO.

The first electrode 134 can be disposed to overlap a portion of the first area A1 of the first semiconductor layer 131. The first electrode 134 can be disposed above the 1-1th area A1-1 of the first area A1 to be in contact with the top surface of the first semiconductor layer 131 exposed by the encapsulation layer 136.

The first electrode 134 can extend from the top surface of the first semiconductor layer 131 disposed in the 1-1th area A1-1 to be disposed along the side surface of the first semiconductor layer 131. Accordingly, the first electrode 134 can overlap the side surface of the first semiconductor layer 131 disposed in the 1-1th area A1-1. At this time, the first electrode 134 can be disposed on the encapsulation layer 136 that covers the side surface of the first semiconductor layer 131. Accordingly, the first electrode 134 can be disposed to overlap the side surface of the first semiconductor layer 131 with the encapsulation layer 136 interposed therebetween, but is not limited thereto.

Meanwhile, when the first semiconductor layer 131 includes the plurality of 1-1th areas A1-1, the light emitting element ED1 can include a plurality of first electrodes 134. The plurality of first electrodes 134 can be disposed to face each other with respect to the center of the light emitting element ED1 and can be disposed to be rotationally symmetrical to each other. But aspects of the present disclosure are not limited thereto. For example, the plurality of first electrodes 134 can be disposed to be spaced diagonally apart from each other with the second electrode 135 interposed therebetween. As illustrated in FIGS. 1 and 2, the plurality of first electrodes 134 can be disposed on an upper left end and a lower right end of the light emitting element ED1, respectively, but is not limited thereto.

The second electrode 135 can be disposed above the encapsulation layer 136 and the second semiconductor layer 133. The second semiconductor layer 133 can be a semiconductor layer doped with p-type impurities, and the second electrode 135 can be an anode.

The second electrode 135 can be made of a conductive material, for example, an opaque conductive material such as titanium (Ti), gold (Au), silver (Ag), copper (Cu), or an alloy thereof, but is not limited thereto. For example, the second electrode 135 can be made of a transparent conductive material such as indium tin oxide ITO or indium zinc oxide IZO.

The second electrode 135 can be disposed to overlap portions of the second area A2 and the first area A1 of the first semiconductor layer 131.

The second electrode 135 can be in contact with the top surface of the second semiconductor layer 133 exposed by the encapsulation layer 136 in the second area A2.

The second electrode 135 can extend in the major axis direction of the light emitting element ED1 and can be disposed to overlap the first area A1. Referring to FIG. 2, the second electrode 135 can extend in an X-axis direction from the lower left and upper right ends of the second area A2 and can overlap the 1-2th area A1-2. Additionally, referring to FIG. 3, the second electrode 135 can be disposed to overlap the top surface of the first semiconductor layer 131 with the encapsulation layer 136 interposed therebetween.

At this time, the second electrode 135 can be disposed to overlap a portion of the side surface of the first semiconductor layer 131 and a portion of the side surface of the second semiconductor layer 133 in the first area A1. Referring to FIGS. 1 and 3, the second electrode 135 can extend from the top surface of the second semiconductor layer 133 disposed in the first area A1 to be disposed along the side surface of the second semiconductor layer 133 and the side surface of the first semiconductor layer 131. At this time, the second electrode 135 can be disposed above the encapsulation layer 136, which covers the side surface of the second semiconductor layer 133, in the second area A2, and can be disposed above the encapsulation layer 136, which covers the side surface of the first semiconductor layer 131, in the plurality of 1-2th areas A1-2. Accordingly, the second electrode 135 can be disposed to overlap the side surface of the first semiconductor layer 131 and the side surface of the second semiconductor layer 133 with the encapsulation layer 136 interposed therebetween, but is not limited thereto.

Referring to FIG. 3, the first insulating layer IL1 can be disposed above the first electrode 134 and the second electrode 135. The first insulating layer IL1 can insulate the first electrode 134 and the second electrode 135 from the polarization inducing layer 137 disposed on the first insulating layer IL1.

The first insulating layer IL1 can planarize top surfaces of the first semiconductor layer 131, the second semiconductor layer 133, the first electrode 134, and the second electrode 135. The first insulating layer IL1 can be made of or include, for example, photoresist or an acryl-based organic material, but is not limited thereto.

The first insulating layer IL1 can expose a portion of a side surface of the light emitting element ED1. For example, as illustrated in FIG. 3, the first insulating layer IL1 can expose the first electrode 134 and the second electrode 135, which can be disposed on the side surfaces of the first semiconductor layer 131, at an edge of the first semiconductor layer 131. But aspects of the present disclosure are not limited thereto.

The polarization inducing layer 137 can be disposed above the first insulating layer IL1. The polarization inducing layer 137 can be disposed on the planarized top surface of the first insulating layer IL1. But aspects of the present disclosure are not limited thereto.

The polarization inducing layer 137 can guide the light emitting element ED1 toward an assembly substrate in an assembly process for applying the light emitting element ED1 to a display device. For example, when the light emitting element ED1 is a light emitting element for assembly, the light emitting element ED1 can be guided to be assembled to the assembly substrate by an electric field, which can be applied to an assembly electrode. At this time, the polarization inducing layer 137 can guide the light emitting element ED1 to the assembly substrate to facilitate the assembly of the light emitting element ED1.

For example, when a bottom surface of the first semiconductor layer 131 in the light emitting element ED1 is referred to as a bottom surface of the light emitting element ED1 and its opposite surface can be referred to as a top surface, the polarization inducing layer 137 can be disposed adjacent to the top surface among the top and bottom surfaces of the light emitting element ED1. Accordingly, when a voltage is applied to the assembly electrode, the light emitting element ED1 can be assembled so that the top surface thereof, on which the polarization inducing layer 137 is disposed, faces the assembly electrode of the assembly substrate. In various aspects of the present disclosure, a top surface, a side surface and a bottom surface can also be referred to as a first surface, a second surface and a third surface.

The polarization inducing layer 137 can be made of or include a metal material or a transparent conductive material. The polarization inducing layer 137 can be made of or include a conductive material, for example, an opaque conductive material, such as titanium (Ti), gold (Au), silver (Ag), copper (Cu), or an alloy thereof, or can be made of a transparent conductive material such as indium tin oxide ITO or indium zinc oxide IZO. But aspects of the present disclosure are not limited thereto.

The polarization inducing layer 137 can extend in a minor axis direction of the light emitting element ED1. For example, referring to FIG. 2, the polarization inducing layer 137 can be disposed to extend along a Y-axis direction. Referring to FIGS. 1 and 2, one end of the polarization inducing layer 137 can overlap the first electrode 134, and another end of the polarization inducing layer 137 can overlap the second electrode 135, but are not limited thereto.

The polarization inducing layer 137 can be disposed to overlap the first area A1 of the light emitting element ED1. Accordingly, as illustrated in FIGS. 1 to 3, the polarization inducing layer 137 can be disposed on both or opposite sides of the light emitting element ED1, not to overlap the second semiconductor layer 133, which can be disposed on a central portion of the light emitting element ED1, but is not limited thereto.

The second insulating layer IL2 that covers top and side surfaces of the polarization inducing layer 137 can further be disposed above the polarization inducing layer 137 and the first insulating layer IL1.

The second insulating layer IL2 can be an insulating layer for insulating the polarization inducing layer 137 and can be made of or include a material such as silicon oxide (SiOx) or silicon nitride (SiNx), but is not limited thereto.

With reference to FIGS. 1-3, the first electrode 134, the second electrode 135 and the polarization inducing layer 137 can include materials that are the same or different from each other. For example, the first electrode 134, the second electrode 135 and the polarization inducing layer 137 can all include a conductive material such as a metal, and the conductive material can be the same or different. But aspects of the present disclosure are not limited thereto. For example, the first electrode 134 and the polarization inducing layer 137 can be formed of or include a metal but the second electrode 135 can be formed of or include the transparent conductive material that can transmit light. Also, the when the first electrode 134 is formed of or include the metal, the second electrode 135 and the polarization inducing layer 137 can include the transparent conductive material. Additionally, at least one of the second electrode 135 and the polarization inducing layer 137 can be formed of or include a combination of materials, such as both the metal and the transparent conductive material. For example, a portion of the second electrode 135 on the side surface of the light emitting element ED1 can be metal and another portion of the second electrode 135 on the top surface of the second semiconductor layer 133 can be the transparent conductive material, but aspects of the present disclosure are not limited thereto.

Also, the polarization inducing layer 137 can substantially overlap with the first area A1 of the light emitting element ED1, and can have a shape that corresponds to a shape of the first area A1, but aspects of the present disclosure are not limited thereto. For example, as shown in FIG. 2, when a surface area of the first area A1 is rectangular, the shape of the polarization inducing layer 137 can be rectangular, but aspects of the present disclosure are not limited thereto, and other shapes can be used. Additionally, dimensions of the polarization inducing layer 137 in terms of a length and a width can correspond to those of the first area A1, but aspects of the present disclosure are not limited thereto.

Further, a portion of the second electrode 135 on the top surface of the second semiconductor layer 133 is provided as rectangular, and provided as overlapping substantially an entire surface of the second area A2 of the first semiconductor layer 131, but aspects of the present disclosure are not limited thereto. For example, the portion of the second electrode 135 on the top surface of the second semiconductor layer 133 can be various shapes, including a mesh shape, a line shape, an annular shape, a curved shape, or a shape having at least one middle hole, but is not limited thereto.

For a light emitting element for assembly, self-assembly can be performed by mixing a plurality of light emitting elements into a fluid. At this time, the plurality of light emitting elements can be assembled on an assembly substrate for transferring the same to a display panel by electric fields applied to assembly electrodes. For example, assembly electrodes and a plurality of openings corresponding to outer diameters of the plurality of light emitting elements and corresponding to the assembly electrodes are formed in the assembly substrate, and the plurality of light emitting elements can be guided to be assembled in the plurality of openings according to electric fields formed in the assembly electrodes of the assembly substrate. But aspects of the present disclosure are not limited thereto.

The light emitting elements guided and disposed on the assembly substrate can be disposed on a display panel later in a manner of being transferred to the display panel.

In this process, it can be very difficult to uniformly apply an electric field to each of the assembly electrodes and assemble the plurality of light emitting elements by distinguishing their directions. For example, in case where the plurality of light emitting elements has a major axis and a minor axis, the plurality of light emitting elements can be assembled on the assembly substrate when the plurality of light emitting elements rotates 180 degrees and 360 degrees, because they have the same outer diameter. At this time, when the plurality of light emitting elements rotates 360 degrees, the first electrodes and the second electrodes of the plurality of light emitting elements can be aligned to be disposed in the same direction on the assembly substrate. However, when the plurality of light emitting elements rotates 180 degrees, the first electrodes and the second electrodes of the plurality of light emitting elements can be aligned in opposite directions on the assembly substrate. This can cause a degradation of an assembly rate of the light emitting elements, or a contact failure or actuation failure of the light emitting elements.

Accordingly, in the light emitting element ED1 according to one example embodiment of the present disclosure, the first electrode 134 and the second electrode 135 can be each disposed to be rotationally symmetrical with respect to the center of the light emitting element ED1. For example, the first electrode 134 and the second electrode 135 can be disposed in the first areas A1 located on both sides of the second area A2 of the light emitting element ED1, but can be disposed alternately along a periphery of the second area A2. Accordingly, even when the light emitting element ED1 rotates 180 degrees, the first electrode 134 and the second electrode 135 can all be disposed in the same direction with respect to the display panel. But aspects of the present disclosure are not limited thereto. Accordingly, even if the light emitting element ED1 rotates, the light emitting element ED1 can be normally connected to the display panel. Thereby actuation failure and contact failure can be minimized and an assembly rate can be improved.

In the light emitting element ED1 according to one example embodiment of the present disclosure, the first electrode 134 and the second electrode 135 disposed on the top surface of the light emitting element ED1 can be covered by a plurality of insulating layers IL, and the first electrode 134 and the second electrode 135 disposed on the side surfaces of the light emitting element ED1 can be exposed by the plurality of insulating layers IL. Accordingly, both the first electrode 134 and the second electrode 135 can be exposed by the same area from the side surfaces of the light emitting element ED1. Accordingly, the light emitting element ED1 and the display panel can be in contact with each other by the same area, and the light emitting element ED1 can be stably connected to the display panel.

In the case of a typical light emitting element for assembly, the light emitting element assembled on an assembly substrate undergoes a transfer process to a donor, and then is transferred from the donor to a display panel. If a bottom surface of a first semiconductor layer of the light emitting element is referred to as a bottom surface of the light emitting element and an opposite surface is referred to as a top surface, the typical light emitting element can be assembled such that the bottom surface thereof faces the assembly substrate. Accordingly, when the light emitting element assembled on the assembly substrate is transferred to the display panel, the light emitting element can be transferred such that the top surface thereof faces the display panel. However, to facilitate connection between the display panel and the light emitting element, the light emitting element must be transferred such that the bottom surface thereof faces the display panel. Accordingly, a process of reversing a direction of the light emitting element can be additionally carried out by proceeding the process of transferring the light emitting element to the donor so that the top surface of the light emitting element assembled on the assembly substrate faces the donor, and transferring the light emitting element transferred to the donor to the display panel.

On the other hand, in the light emitting element ED1 according to one example embodiment of the present disclosure, a process of separately transferring the light emitting element ED1 assembled on the assembly substrate to the donor can be not performed. In the light emitting element ED1 according to one example embodiment of the present disclosure, the polarization inducing layer 137 can be disposed on the top surface of the light emitting element ED1. Accordingly, the polarization inducing layer 137 can be dielectrically polarized by the assembly substrate and can allow the light emitting element ED1 to be assembled on the assembly substrate, and the top surface of the light emitting element ED1 can be assembled to face the assembly substrate. Accordingly, when the light emitting element ED1 transferred to the assembly substrate is transferred to the display panel, the transfer can be made such that the bottom surface of the light emitting element faces the display panel. Therefore, in the light emitting element ED1 according to one example embodiment of the present disclosure, an additional process of transferring the light emitting element ED1 assembled on the assembly substrate to the donor to reverse the direction of the light emitting element can be not performed. Therefore, the light emitting element ED1 transferred to the assembly substrate can be directly transferred to the display panel so that the bottom surface of the light emitting element ED1 faces the display panel. Thereby manufacturing processes and manufacturing costs for a display device can be reduced.

In the light emitting element ED1 according to one example embodiment of the present disclosure, the polarization inducing layer 137 can be disposed on both or opposite sides of the light emitting element ED1. Accordingly, light traveling in the lateral direction among light generated in the light emitting layer 132 of the light emitting element ED1 can be extracted to the outside of the light emitting element ED1 through the polarization inducing layer 137. In this instance, the traveling direction of light generated in the light emitting element ED1 can be changed on the surface of the polarization inducing layer 137 such that the light proceeds in a forward direction. Therefore, in the light emitting element ED1 according to one example embodiment of the present disclosure, the polarization inducing layer 137 disposed on the side surface of the light emitting element ED1 can improve light extraction efficiency, and change a light path formed in a lateral direction to a light path formed in a forward direction. Thereby viewing angle deviation can be reduced.

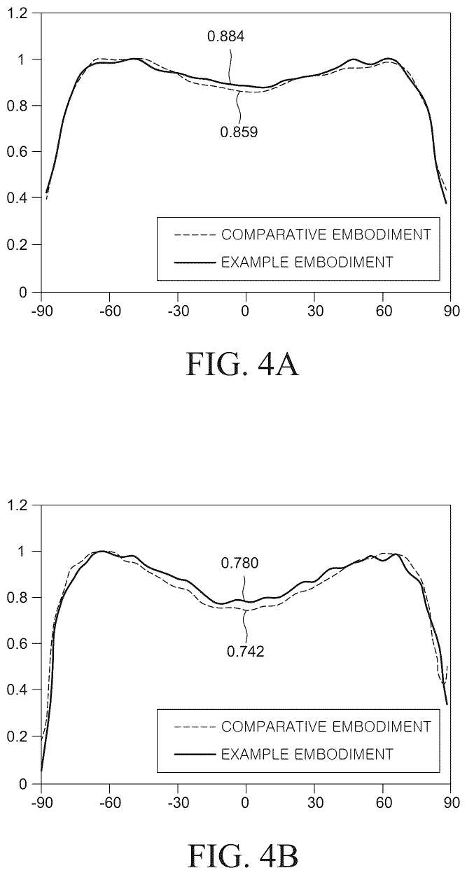

FIGS. 4A and 4B are graphs for explaining effects of a light emitting element according to one example embodiment of the present disclosure. Particularly, FIG. 4A is a graph for explaining luminance distribution according to a viewing angle in a minor axis direction of the light emitting element, and FIG. 4B is a graph for explaining luminance distribution according to a viewing angle in a major axis direction of the light emitting element. The example embodiment of FIGS. 4A and 4B corresponds to the light emitting element ED1 according to one example embodiment of the present disclosure, and the comparative embodiment of FIGS. 4A and 4B is merely different from the example embodiment in that a plurality of insulating layers IL and the polarization inducing layer 137 are not disposed. In the graphs of FIGS. 4A and 4B, an X axis indicates a viewing angle. In the graphs of FIGS. 4A and 4B, a Y axis indicates luminance, and the maximum luminance is set to 1 in each of the comparative embodiment and the example embodiment.

Referring to FIGS. 4A and 4B, the comparative embodiment and the example embodiment show higher luminance in the lateral direction than in the forward direction, and show the maximum luminance at about 60°.

The results according to the graphs of FIGS. 4A and 4B are summarized in [Table 1] below.

TABLE 1

| | Frontal luminance in | Frontal luminance in |
|---|---|---|
| | minor axis direction | major axis direction |
| Comparative | 0.859 | 0.742 |
| embodiment | | |
| Example | 0.884 | 0.78 |
| embodiment | | |

Referring to FIG. 4A and Table 1, it can be seen that the central luminance in the example embodiment is 0.884, which is more improved than the central luminance of 0.859 in the comparative embodiment.

Referring to FIG. 4B and Table 1, it can be seen that the central luminance in the example embodiment is 0.78, which is more improved than the central luminance of 0.742 in the comparative embodiment.

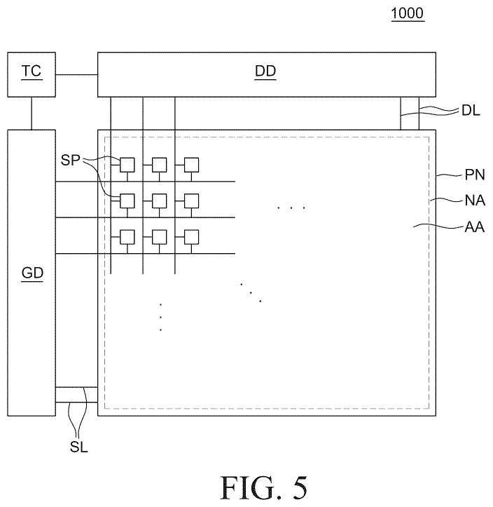

FIG. 5 is a block diagram schematically illustrating a configuration of a display device according to one example embodiment of the present disclosure. For convenience of explanation, a display device 1000, a gate driver GD, a data driver DD, and a timing controller TC are merely shown in FIG. 5 among various components of the display device 1000.

Referring to FIG. 5, the display device 1000 can include a gate driver GD and a data driver DD that supply various signals, and a timing controller TC that controls the gate driver GD and the data driver DD.

The gate driver GD supplies a plurality of scan signals to a plurality of scan lines SL according to a plurality of gate control signals provided from the timing controller TC. It is shown in FIG. 5 that one gate driver GD is disposed on one side of the display device 1000 in a spaced manner, but the number and disposition of gate drivers GD are not limited thereto.

The data driver DD converts image data, which is input from the timing controller TC, into a data voltage using a reference gamma voltage according to a plurality of data control signals provided from the timing controller TC. The data driver DD can supply the converted data voltage to a plurality of data lines DL.

The timing controller TC arranges image data input from outside and supplies the same to the data driver DD. The timing controller TC can generate a gate control signal and a data control signal using a synchronization signal input from the outside, for example, a dot clock signal, a data enable signal, and a horizontal/vertical synchronization signal. In addition, the timing controller TC can supply the generated gate control signal and data control signal to the gate driver GD and the data driver DD, respectively, to control the gate driver GD and data driver DD. But aspects of the present disclosure are not limited thereto.

The display device 1000 can include a plurality sub pixels SP as a component for displaying an image to a user.

On the display device 1000, an active area AA and a non-active area NA surrounding the active area AA can be defined.

The active area AA is an area where an image is displayed on the display device 1000. The plurality of sub pixels SP constituting a plurality of pixels and a circuit for driving the plurality of sub pixels SP can be disposed in the active area AA. The plurality of sub pixels SP is the minimum unit constituting the active area AA, and n sub pixels SP can constitute one pixel. A light emitting element, a thin film transistor for driving the light emitting element, and the like can be disposed in each of the plurality of sub pixels SP. A plurality of light emitting elements can be defined differently depending on the type of display device 1000. For example, if the display device 1000 is an inorganic light emitting display panel, the light emitting element can be a light-emitting diode (LED) or a micro light-emitting diode (micro-LED). But aspects of the present disclosure are not limited thereto.

A plurality of lines that transmits various signals to the plurality of sub pixels SP can be disposed in the active area AA. For example, the plurality of lines can include a plurality of data lines DL for supplying data voltages to the plurality of sub pixels SP, respectively, and a plurality of scan lines SL for supplying scan signals to the plurality of sub pixels SP, respectively, and the like. The plurality of scan lines SL can extend in one direction in the active area AA to be connected to the plurality of sub pixels SP, and the plurality of data lines DL can extend in a direction different from the one direction in the active area AA to be connected to the plurality of sub pixels SP. In addition, a low-potential power line, a high-potential power line, etc. can be further disposed in the active area AA, but are not limited thereto.

The non-active area NA is an area where an image is not displayed and can be defined as an area extending from the active area AA. A link line and a pad electrode for transmitting a signal to the sub pixel SP of the active area AA, driver ICs such as a gate driver IC and a data driver IC, or the like can be disposed in the non-active area NA.

However, the non-active area NA can be located on a rear surface of the display device 1000, for example, on a surface without the sub pixel SP, or can be omitted, and is not limited to what is shown in the drawings.

Meanwhile, the drivers such as the gate driver GD, the data driver DD, and the timing controller TC can be connected to the display device 1000 in various ways. For example, the gate driver GD can be mounted in the non-active area NA in a gate in panel (GIP) manner, or can be mounted between the plurality of sub pixels SP in the active area AA in a gate in active (GIA) manner. For example, the data driver DD and the timing controller TC can be disposed separately on a flexible film and a printed circuit board (PCB). The flexible film and the PCB can be bonded on the pad electrode formed in the non-active area NA of the display device 1000, such that the data driver DD and the timing controller TC can be electrically connected to the display device 1000. But aspects of the present disclosure are not limited thereto.

If the gate driver GD is mounted in the GIP manner and the data driver DD and the timing controller TC transmit signals to the display device 1000 through the pad electrode of the non-active area NA, the non-active area NA needs an area of a predetermined level or more for disposing the gate driver GD and the pad electrode, which can cause an increase in a bezel size.

In contrast, when the gate driver GD is mounted inside the active area AA in the GIA manner and the flexible film and the PCB are bonded on the rear surface of the display device 1000 by forming a side wiring line for connecting the signal line on the front surface of the display device 1000 and the pad electrode on the rear surface of the display device 1000, the non-active area NA can be minimized on the front surface of the display device 1000. In other words, when the gate driver GD, the data driver DD, and the timing controller TC are connected to the display device 1000 in the above manner, it can be possible to implement a zero bezel that a bezel does not substantially exist.

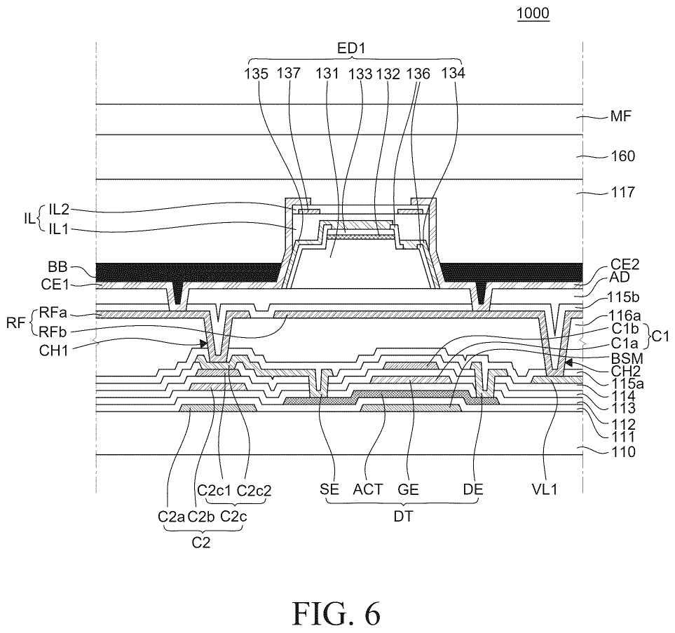

FIG. 6 is a cross-sectional view illustrating a pixel area of a display device according to one example embodiment of the present disclosure.

Referring to FIG. 6, the display device 1000 can include a substrate 110, a light shielding layer BSM, a buffer layer 111, a gate insulating layer 112, a first interlayer insulating layer 113, a second interlayer insulating layer 114, a first passivation layer 115a, a second passivation layer 115b, a first planarization layer 116a, a second planarization layer 116b, a third planarization layer 116c, a protection layer 117, a cover layer 160, an optical film MF, a light emitting element ED1, a first connection electrode CE1, a second connection electrode CE2, a driving transistor DT, a high-potential power line VL1, a reflection plate RF, a first capacitor C1, and a second capacitor C2. But aspects of the present disclosure are not limited thereto. For example, some of the layers need not be used, or additional layers can be used.

The display device 1000 can include a substrate 110. The substrate 110 is a substrate that supports components disposed on top of the display device 1000 and can be an insulating substrate. A plurality of sub pixels SP can be formed on the substrate 110 to display an image. For example, the substrate 110 can be made of glass or resin. Additionally, the substrate 110 can be made of polymer or plastic. In some example embodiments, the substrate 110 can be made of a plastic material with flexibility.

The plurality of sub pixels SP can be disposed on the substrate 110 to form a plurality of rows and a plurality of columns. Each of the plurality of sub pixels SP can include a light emitting element ED1 and a pixel circuit to independently emit light.

The plurality of sub pixels SP can include a first sub pixel, a second sub pixel, and a third sub pixel that emit light of different colors. For example, the first sub pixel can be a red sub pixel, the second sub pixel can be a green sub pixel, and the third sub pixel can be a blue sub pixel, but are not limited thereto.

A first light emitting element can be disposed in the first sub pixel, a second light emitting element can be disposed in the second sub pixel, and a third light emitting element can be disposed in the third sub pixel. For example, the first light emitting element can be a red light emitting element, the second light emitting element can be a green light emitting element, and the third light emitting element can be a blue light emitting element, but are not limited thereto.

A plurality of lines that supply various signals to the plurality of sub pixels SP can be disposed on the substrate 110. For example, a plurality of data lines DL, a plurality of high-potential power lines VL1, and a plurality of low-potential power lines can be disposed on the substrate 110 to extend in the column direction. For example, a plurality of light emission control signal lines, a plurality of auxiliary high-potential power lines, a plurality of auxiliary low-potential power lines, and a plurality of scan lines can be disposed on the substrate 110 to extend in the row direction. Additionally, the high-potential power line VL1 extending in the column direction can be electrically connected to the auxiliary high-potential power line extending in the row direction through a contact hole. In this instance, the emission control signal line can transmit an emission control signal to the pixel circuit of each of the plurality of sub pixels SP, thereby controlling emission timing of each of the plurality of sub pixels SP. However, the types of the plurality of lines described above are merely illustrative, and the types of the plurality of lines that can actually be used can vary depending on the design.

A pixel circuit for driving the light emitting element ED1 can be disposed in each of the plurality of sub pixels SP on the substrate 110. The pixel circuit can include a plurality of thin film transistors and a plurality of capacitors. In FIG. 6, for convenience of explanation, only a driving transistor DT, a first capacitor C1, and a second capacitor C2 are merely shown among components of the pixel circuit. However, the pixel circuit can further include a switching transistor, a sensing transistor, an emission control transistor, etc., but is not limited thereto.

The substrate 110 can include thereon a light shielding layer BSM, a driving transistor DT, a first capacitor C1, a second capacitor C2, a reflection plate RF, a plurality of light emitting elements ED1, a first connection electrode CE1, a second connection electrode CE2, a bank BB, a protection layer 117, a cover layer 160, an optical film MF, and insulating layers including a plurality of inorganic insulating layers and a plurality of organic insulating layers. But aspects of the present disclosure are not limited thereto.

Among the insulating layers disposed on the substrate 110, the plurality of inorganic insulating layers can include a buffer layer 111, a gate insulating layer 112, a first interlayer insulating layer 113, a second interlayer insulating layer 114, a first passivation layer 115a, and a second passivation layer 115b.

In addition, among the insulating layers disposed on the substrate 110, the plurality of organic insulating layers can include a first planarization layer 116a, an adhesive layer AD, a second planarization layer 116b, and a third planarization layer 116c.

A light shielding layer BSM can be disposed on the substrate 110. The light shielding layer BSM can minimize leakage current by shielding light incident on active layers ACT of a plurality of transistors. For example, the light shielding layer BSM can be disposed below the active layer ACT of the driving transistor DT to shield light incident on the active layer ACT. If light is irradiated to the active layer ACT, a leakage current can occur and the reliability of the transistor can decrease. Accordingly, the reliability of the driving transistor DT can be improved by disposing the light shielding layer BSM on the substrate 110 to block light. The light shielding layer BSM can be made of an opaque conductive material, for example, copper (Cu), aluminum (Al), molybdenum (Mo), nickel (Ni), titanium (Ti), chromium (Cr), or an alloy thereof, but is not limited thereto.

The buffer layer 111 can be disposed on the light shielding layer BSM. The buffer layer 111 can be an inorganic insulating layer that can reduce permeation of moisture or impurities through the substrate 110. For example, the buffer layer 111 can be configured as a single layer or a multi-layer of silicon oxide (SiOx) or silicon nitride (SiNx), but is not limited thereto. Additionally, the buffer layer 111 can be omitted depending on the type of the substrate 110 or the type of a thin film transistor, but is not limited thereto.

A driving transistor DT including an active layer ACT, a gate electrode GE, a source electrode SE, and a drain electrode DE can be disposed above the buffer layer 111.

Meanwhile, an additional buffer layer can be disposed between the substrate 110 and the light shielding layer BSM. The additional buffer layer can be an inorganic insulating layer that can reduce the permeation of moisture or impurities through the substrate 110 in the same way as the buffer layer 111 described above. For example, the additional buffer layer can be configured as a single layer or a multi-layer of silicon oxide (SiOx) or silicon nitride (SiNx), but is not limited thereto.

First, the active layer ACT of the driving transistor DT can be disposed on the buffer layer 111. The active layer ACT can be made of a semiconductor material such as oxide semiconductor, amorphous silicon, or polysilicon, but is not limited thereto. In addition, the driving transistor DT, other transistors such as a switching transistor, a sensing transistor, an emission control transistor, etc., can be additionally disposed. The active layers of these transistors can also be made of a semiconductor material such as an oxide semiconductor, amorphous silicon, or polysilicon, but are not limited thereto. Additionally, the active layers of the transistors, included in the pixel circuit, such as the driving transistor DT, the switching transistor, the sensing transistor, and the emission control transistor, can be made of the same material or can be made of different materials.

The gate insulating layer 112 can be disposed on the active layer ACT. The gate insulating layer 112 can be an inorganic insulating layer to electrically insulate the active layer ACT from the gate electrode GE, and can be configured as a single layer or a multi-layer of silicon oxide (SiOx) or silicon nitride (SiNx), but is not limited thereto.

A gate electrode GE can be disposed on the gate insulating layer 112. The gate electrode GE can be made of a conductive material, for example, copper (Cu), aluminum (Al), molybdenum (Mo), nickel (Ni), titanium (Ti), chromium (Cr), or an alloy thereof, but is not limited thereto.

A first interlayer insulating layer 113 and a second interlayer insulating layer 114 can be disposed on the gate electrode GE. Contact holes can be formed in the first interlayer insulating layer 113 and the second interlayer insulating layer 114 to connect each of the source electrode SE and the drain electrode DE to the active layer ACT. The first interlayer insulating layer 113 and the second interlayer insulating layer 114 can be inorganic insulating layers to protect components therebelow, and can be configured as a single layer or a multi-layer of silicon oxide (SiOx) or silicon nitride (SiNx), but are not limited thereto.

A source electrode SE and a drain electrode DE that are electrically connected to the active layer ACT can be disposed on the second interlayer insulating layer 114. The source electrode SE can be connected to the second capacitor C2 and the first electrode 134 of the light emitting element ED1, and the drain electrode DE can be connected to other components of the pixel circuit. The source electrode SE and the drain electrode DE can be made of a conductive material, for example, copper (Cu), aluminum (Al), molybdenum (Mo), nickel (Ni), titanium (Ti), chromium (Cr), or an alloy thereof, but is not limited thereto.

A plurality of high-potential power lines VL1 can be disposed on the second interlayer insulating layer 114. The plurality of high-potential power lines VL1 can transmit high-potential power voltages to the light emitting elements ED1 of the plurality of sub pixels SP, respectively. The plurality of high-potential power lines VL1 can be made of a conductive material, for example, copper (Cu), aluminum (Al), molybdenum (Mo), nickel (Ni), titanium (Ti), chromium (Cr), or an alloy thereof, but is not limited thereto.

Next, the first capacitor C1 can be disposed on the gate insulating layer 112. The first capacitor C1 can include a 1-1th capacitor electrode C1a and a 1-2th capacitor electrode C1b. But aspects of the present disclosure are not limited thereto.

First, the 1-1th capacitor electrode C1a can be disposed on the gate insulating layer 112. The 1-1th capacitor electrode C1a can be integrally formed with the gate electrode GE of the driving transistor DT. But aspects of the present disclosure are not limited thereto.

The 1-2th capacitor electrode C1b can be disposed on the first interlayer insulating layer 113. The 1-2th capacitor electrode C1b can be disposed to overlap the 1-1th capacitor electrode C1a with the first interlayer insulating layer 113 interposed therebetween. But aspects of the present disclosure are not limited thereto.

Accordingly, the first capacitor C1 can be connected to the gate electrode GE of the driving transistor DT to maintain a voltage of the gate electrode GE of the driving transistor DT for a certain period of time.

Next, the second capacitor C2 can be disposed on the substrate 110. The second capacitor C2 can include a 2-1th capacitor electrode C2a, a 2-2th capacitor electrode C2b, and a 2-3th capacitor electrode C2c. The second capacitor C2 can include a 2-1th capacitor electrode C2a as a lower capacitor electrode, a 2-2th capacitor electrode C2b as an intermediate capacitor electrode, and a 2-3th capacitor electrode C2c as an upper capacitor electrode. But aspects of the present disclosure are not limited thereto.

The 2-1th capacitor electrode C2a can be disposed on the substrate 110. The 2-1th capacitor electrode C2a can be disposed on the same layer as the light shielding layer BSM and can be made of the same material. But aspects of the present disclosure are not limited thereto.

The 2-2th capacitor electrode C2b can be disposed on the buffer layer 111 and the gate insulating layer 112. The 2-2th capacitor electrode C2b can be disposed on the same layer as the gate electrode GE and can be made of the same material. But aspects of the present disclosure are not limited thereto.

The 2-3th capacitor electrode C2c can be disposed on the first interlayer insulating layer 113. The 2-3th capacitor electrode C2c can include a first layer C2c1 and a second layer C2c2. The first layer C2c1 of the 2-3th capacitor electrode C2c can be made of the same material on the same layer as the 1-2th capacitor electrode C1b. The first layer C2c1 can be disposed to overlap the 2-1th capacitor electrode C2a and the 2-2th capacitor electrode C2b with the first interlayer insulating layer 113 interposed therebetween. But aspects of the present disclosure are not limited thereto.

The second layer C2c2 of the 2-3th capacitor electrode C2c can be disposed on the second interlayer insulating layer 114. The second layer C2c2 can be a portion extending from the source electrode SE of the driving transistor DT and can be connected to the first layer C2c1 through a contact hole of the second interlayer insulating layer 114. But aspects of the present disclosure are not limited thereto.

Accordingly, the second capacitor C2 can be electrically connected between the source electrode SE of the driving transistor DT and the light emitting element ED1 to increase capacitance existing in the light emitting element ED1, and allow light with higher luminance to be emitted from the light emitting element ED1.

The first passivation layer 115a can be disposed on the driving transistor DT, the first capacitor C1, and the second capacitor C2. The first passivation layer 115a can be an inorganic insulating layer to protect components below the first passivation layer 115a, and can be made of an inorganic material such as silicon oxide (SiOx) or silicon nitride (SiNx), but is not limited thereto.

A first planarization layer 116a can be disposed on the first passivation layer 115a. The first planarization layer 116a can planarize an upper portion of the pixel circuit including the driving transistor DT. The first planarization layer 116a can be configured as a single layer or a multi-layer, for example, can be configured as a benzocyclobutene or acryl-based organic insulating layer. But aspects of the present disclosure are not limited thereto.

Referring to FIG. 6, a plurality of reflection plates RF can be disposed on the first planarization layer 116a. The reflection plate RF can be a component for reflecting light emitted from the plurality of light emitting elements ED1 to the upper portion of the substrate 110, and can be configured in a shape corresponding to each of the plurality of sub pixels SP. One reflection plate RF can be disposed to cover most of the area of one sub pixel SP. The reflection plate RF can reflect light emitted from the light emitting element ED1 and simultaneously be used as an electrode to electrically connect the light emitting element ED1 and the pixel circuit. Accordingly, the reflection plate RF can include various conductive layers in consideration of light reflection efficiency and resistance. For example, the reflection plate RF can be configured by using an opaque conductive layer such as silver (Ag), aluminum (Al), molybdenum (Mo), titanium (Ti), or an alloy thereof together with a transparent conductive layer such as indium tin oxide ITO, but the structure of the reflection plate RF is not limited thereto.

The reflection plate RF can include a plurality of first reflection plates RFa and a plurality of second reflection plates RFb disposed on the plurality of sub pixels SP, respectively. But aspects of the present disclosure are not limited thereto.

Each of the plurality of first reflection plates RFa can reflect light emitted from the light emitting element ED1 to the outside of the display device 1000. The first reflection plate RFa can be disposed on the driving transistor DT in each sub pixel SP, to be electrically connected to the source electrode SE of the driving transistor DT and the second capacitor C2 through a first contact hole CH1.

Each of the plurality of second reflection plates RFb can be disposed to overlap the light emitting element ED1. The second reflection plate RFb can be disposed on the driving transistor DT in each sub pixel SP and connected to the high-potential power line VL1 through a second contact hole CH2. Accordingly, the second reflection plate RFb can reflect light emitted from the light emitting element ED1 to the outside of the display device 1000 while supplying a high-potential power voltage to the light emitting element ED1.

Meanwhile, the plurality of light emitting elements ED1 can be separately connected to the high-potential power lines VL1 without being connected to the reflection plates RF, but are not limited thereto.

A second passivation layer 115b can be disposed on the plurality of reflection plates RF. The second passivation layer 115b can be an inorganic insulating layer to protect components below the second passivation layer 115b, and can be configured as a single layer or a multi-layer of silicon oxide (SiOx) or silicon nitride (SiNx), but is not limited thereto.

An adhesive layer AD can be disposed on the second passivation layer 115b. The adhesive layer AD can be disposed on the front surface of the substrate 110 to fix the light emitting element ED1 disposed on the adhesive layer AD. The adhesive layer AD can be made of an organic insulating layer. The adhesive layer AD can be made of a photocurable adhesive material that can be cured by light. For example, the adhesive layer AD can be made of an acrylic-based material containing a photoresist, but is not limited thereto.

The plurality of light emitting elements ED1 can be disposed in the plurality of sub pixels SP, respectively, on the adhesive layer AD. The light emitting elements ED1 can be elements that emit light by current, and can include a first light emitting element that emits red light, a second light emitting element that emits green light, and a third light emitting element that emits blue light. The combination of these light emitting elements can produce light of various colors, including white. For example, the light emitting element ED1 can be a light emitting diode (LED) or a micro LED, but is not limited thereto.

Each of the plurality of light emitting elements ED1 can include a first semiconductor layer 131, a light emitting layer 132, a second semiconductor layer 133, a first electrode 134, a second electrode 135, an encapsulation layer 136, a plurality of insulating layers IL, and a polarization inducing layer 137. Hereinafter, a description will be made on the assumption that the plurality of light emitting elements ED1 has a lateral structure, but the type of the plurality of light emitting elements ED1 is not limited thereto. Additionally, it is described in FIG. 6 that the light emitting element ED1 described in FIGS. 1 to 3 is applied as the plurality of light emitting elements ED1. Since the plurality of light emitting elements ED1 has been described in detail with reference to FIGS. 1 to 3, a redundant description will be omitted or may be briefly provided.

Next, a first connection electrode CE1 and a second connection electrode CE2 can be disposed on the adhesive layer AD and the plurality of light emitting elements ED1.

The first connection electrode CE1 can be an electrode that electrically connects the first electrode 134 of the light emitting element ED1 and the driving transistor DT. The first connection electrode CE1 can be electrically connected to the first electrode 134 that is exposed on the side surface of the light emitting element ED1. Additionally, the first connection electrode CE1 can be electrically connected to the first reflection plate RFa through contact holes formed through the adhesive layer AD and the second passivation layer 115b. Accordingly, the first electrode 134 and the source electrode SE of the driving transistor DT can be electrically connected through the first connection electrode CE1 and the first reflection plate RFa.

The second connection electrode CE2 can be an electrode that electrically connects the second electrode 135 of the light emitting element ED1 and the high-potential power line VL1. The second connection electrode CE2 can be electrically connected to the second electrode 135 that is exposed on the side surface of the light emitting element ED1. Additionally, the second connection electrode CE2 can be connected to the second reflection plate RFb through contact holes formed through the adhesive layer AD and the second passivation layer 115b. Accordingly, the second electrode 135 and the high-potential power line VL1 can be electrically connected through the second connection electrode CE2.

Meanwhile, the first connection electrode CE1 and the second connection electrode CE2 can extend from the side surface of the light emitting element ED1 to cover the top surface of the adhesive layer AD. Accordingly, the first connection electrode CE1 and the second connection electrode CE2 can be disposed on the same layer as the light emitting element ED1, but are not limited thereto.

Meanwhile, considering a process margin, the first connection electrode CE1 and the second connection electrode CE2 can extend from the side surface of the light emitting element ED1 and can be disposed to overlap the top surface of the light emitting element ED1. For example, as shown in FIG. 6, the first connection electrode CE1 and the second connection electrode CE2 can cover portions of the side surface of the first insulating layer IL and the side surface and top surface of the second insulating layer IL2, but are not limited thereto.

Meanwhile, when the first connection electrode CE1 and the second connection electrode CE2 can be disposed on the top surface of the light emitting element ED1, the first connection electrode CE1 and the second connection electrode CE2 can be in a state insulated from the polarization inducing layer 137 by the plurality of insulating layers IL of the light emitting element ED1.

The first connection electrode CE1 and the second connection electrode CE2 can be made of or include a transparent conductive material such as indium tin oxide ITO or indium zinc oxide IZO, but are not limited thereto.

Meanwhile, in the drawings, the first electrode 134, the first connection electrode CE1, and the first reflection plate RFa are shown as being electrically connected to the source electrode SE of the driving transistor DT, but the first electrode 134, the first connection electrode CE1, and the first reflection plate RFa can be connected to the drain electrode DE of the driving transistor DT, but are not limited thereto.

Also, when the first connection electrode CE1 and the second connection electrode CE2 are disposed on the top surface of the light emitting element ED1, for example, on a top surface of the second insulating layer IL2, respective edges of the first connection electrode CE1 and the second connection electrode CE2 can extend toward a middle of the second area A2 of the second semiconductor layer 133, but not overlap the second area A2. For example, the edges of the first connection electrode CE1 and the second connection electrode CE2 can extend beyond the polarization inducing layer 137 so as to entirely overlap the polarization inducing layer 137, or can only partially overlap the polarization inducing layer 137. In other aspects of the present disclosure, the first connection electrode CE1 and the second connection electrode CE2 can be not overlapping the polarization inducing layer 137.

Referring to FIG. 6, a bank BB can be disposed on the first connection electrode CE1 and the second connection electrode CE2. The bank BB can cover portions of the first connection electrode CE1 and the second connection electrode CE2. Additionally, the bank BB can be disposed on the adhesive layer AD at a certain distance from the light emitting element ED1, for example.

The bank BB can be disposed to be spaced apart at a certain distance from the light emitting element ED1 and at least a portion of the bank BB can overlap the reflection plate RF. For example, the bank BB can be disposed not to overlap the light emitting element ED1 and can be disposed to surround a peripheral area of the light emitting element ED1.

The bank BB can be made of an opaque material to reduce color mixing between the plurality of sub pixels SP. For example, the bank BB can be made of black resin, but is not limited thereto.

A protection layer 117 can be disposed on the first connection electrode CE1, the second connection electrode CE2, and the bank BB. The protection layer 117 is a layer to protect components below the protection layer 117. The protection layer 117 can be configured as a single layer or a multi-layer, and can be made of, for example, benzocyclobutene, light-transmitting epoxy, photoresist, or an acryl-based organic material, but is not limited thereto.

A cover layer 160 can be disposed on the protection layer 117.

The cover layer 160 is a layer for minimizing permeation of moisture from the outside of the display device 1000 and encapsulating the components that the cover layer 160 surrounds. The cover layer 160 can be disposed to surround the front, side, and rear surfaces of the substrate 110.

The cover layer 160 can be made of a material with low moisture permeability and high insulating properties. For example, the cover layer 160 can be made of a material containing parylene, but is not limited thereto.

An optical film MF covering the top of the cover layer 160 can be disposed on the entire upper area of the substrate 110. The optical film MF can be disposed on the protection layer 117. The optical film MF can be a functional film that protects the display device 1000 and implements higher-quality images. For example, the optical film MF can include an anti-scattering film, an anti-glare film, an anti-reflecting film, a low-reflecting film, an OLED transmittance controllable film, a polarizer, etc., but is not limited thereto.

Meanwhile, an adhesive portion can be disposed between the protection layer 117 and the optical film MF on the top of the substrate 110. The adhesive portion can be formed on the front surface of the substrate 110 to bond the protection layer 117 and the optical film MF. The adhesive portion can be made of a photocurable adhesive material that can be cured by light. For example, the adhesive portion can be made of an acrylic-based material containing a photoresist, but is not limited thereto.

The example embodiments of the present disclosure can also be described as follows:

According to an aspect of the present disclosure, there is provided a light emitting element. The light emitting element comprises a first semiconductor layer, a light emitting layer disposed on the first semiconductor layer, a second semiconductor layer disposed on the light emitting layer, a first electrode disposed on the first semiconductor layer, a second electrode disposed on the second semiconductor layer, a first insulating layer disposed on the first electrode and the second electrode, and a polarization inducing layer disposed on the first insulating layer.

The first insulating layer can insulate the first electrode and the second electrode from the polarization inducing layer.

One end of the polarization inducing layer can overlap the first electrode, and another end of the polarization inducing layer can overlap the second electrode.

The polarization inducing layer can be disposed not to overlap the second semiconductor layer.

The first insulating layer can planarize a top surface of the first semiconductor layer and a top surface of the second semiconductor layer. The polarization inducing layer can be disposed on a flat top surface of the first insulating layer.

The first semiconductor layer can include a first area non-overlapping the second semiconductor layer, and a second area overlapping the second semiconductor layer. The second electrode can be disposed to overlap portions of the second area and the first area.

The second electrode can be in contact with the second semiconductor layer in the second area and extend to the first area to overlap a portion of a side surface of the first semiconductor layer and a portion of a side surface of the second semiconductor layer.

The light emitting element can further comprise an encapsulation layer surrounding top and side surfaces of the first semiconductor layer. The encapsulation layer can be disposed to overlap a portion of the first area to insulate the second electrode and the first semiconductor layer.

The encapsulation layer can cover both side surfaces of the first semiconductor layer. The first electrode and the second electrode can be disposed on the encapsulation layer to overlap the side surfaces of the first semiconductor layer.

The first area can include a plurality of 1-1th areas overlapping the first electrode, and a plurality of 1-2th areas overlapping the second electrode. The plurality of 1-1th areas and the plurality of 1-2th areas can be alternately disposed along a periphery of the second area.

A plurality of first electrodes can be disposed in the plurality of 1-1th areas, and the plurality of first electrodes can be disposed to be spaced apart in a diagonal direction with the second electrode interposed therebetween.

The polarization inducing layer can be made of a metal material or a transparent conductive material.

The light emitting element can further comprise a second insulating layer disposed to cover top and side surfaces of the polarization inducing layer.

The first insulating layer can be made of an organic insulating material, and the second insulating layer can be made of an inorganic insulating material.

According to an aspect of the present disclosure, there is provided a display device. The display device comprises a substrate including a plurality of sub pixels, a plurality of light emitting elements disposed in the plurality of sub pixels on the substrate, a plurality of transistors disposed on the substrate, and a connection electrode connecting the plurality of transistors and the plurality of light emitting elements. Each of the plurality of light emitting elements can include a polarization inducing layer. The connection electrode is electrically connected to the plurality of light emitting elements on side surfaces of the plurality of light emitting elements.

Each of the plurality of light emitting elements can include a first semiconductor layer, a light emitting layer disposed on the first semiconductor layer, a second semiconductor layer disposed on the light emitting layer, a first electrode disposed on the first semiconductor layer, a second electrode disposed on the second semiconductor layer, a first insulating layer disposed on the first electrode and the second electrode, and the polarization inducing layer disposed on the first insulating layer. The connection electrode can be in an insulated state from the polarization inducing layer.

Each of the plurality of light emitting elements can further include a second insulating layer disposed on the polarization inducing layer, and the connection electrode can cover a portion of a top surface of the second insulating layer.

The connection electrode can be disposed on the same layer as the plurality of light emitting elements in an area excluding the plurality of light emitting elements.

Although the example embodiments of the present disclosure have been described in detail with reference to the accompanying drawings, the present disclosure is not limited thereto and can be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. The protective scope of the present disclosure should be construed based on the following claims, and all the technical concepts in the equivalent scope thereof should be construed as falling within the scope of the present disclosure.

What is claimed is:

1. A light emitting element comprising:
a first semiconductor layer;
a light emitting layer on the first semiconductor layer;
a second semiconductor layer on the light emitting layer;
a first electrode on the first semiconductor layer;
a second electrode on the second semiconductor layer;
a first insulating layer on the first electrode and the second electrode; and
a polarization inducing layer on the first insulating layer.

2. The light emitting element of claim 1, wherein the first insulating layer insulates the first electrode and the second electrode from the polarization inducing layer.

3. The light emitting element of claim 1, wherein one end of the polarization inducing layer overlaps the first electrode, and
wherein another end of the polarization inducing layer overlaps the second electrode.

4. The light emitting element of claim 3, wherein the polarization inducing layer does not overlap with the second semiconductor layer.

5. The light emitting element of claim 1, wherein the first insulating layer planarizes a first surface of the first semiconductor layer and a first surface of the second semiconductor layer, and
wherein the polarization inducing layer is disposed on a flat first surface of the first insulating layer.

6. The light emitting element of claim 1, wherein the first semiconductor layer includes:
a first area non-overlapping the second semiconductor layer; and
a second area overlapping the second semiconductor layer, and
wherein the second electrode is disposed to overlap portions of the second area and the first area, respectively.

7. The light emitting element of claim 6, wherein the second electrode is in contact with the second semiconductor layer in the second area and extends to the first area to overlap a portion of a second surface of the first semiconductor layer and a portion of a second surface of the second semiconductor layer.

8. The light emitting element of claim 6, further comprising an encapsulation layer surrounding first and second surfaces of the first semiconductor layer,
wherein the encapsulation layer is disposed to overlap a portion of the first area to insulate the second electrode and the first semiconductor layer.

9. The light emitting element of claim 8, wherein the encapsulation layer covers opposite second surfaces of the first semiconductor layer, and
wherein the first electrode and the second electrode are disposed on the encapsulation layer to overlap the opposite second surfaces of the first semiconductor layer.

10. The light emitting element of claim 6, wherein the first area includes:
a plurality of 1-1th areas overlapping the first electrode; and
a plurality of 1-2th areas overlapping the second electrode, and
wherein the plurality of 1-1th areas and the plurality of 1-2th areas are alternately disposed along a periphery of the second area.

11. The light emitting element of claim 10, wherein a plurality of first electrodes including the first electrode are disposed in the plurality of 1-1th areas, and
wherein the plurality of first electrodes are disposed to be spaced apart in a diagonal direction with the second electrode interposed therebetween.

12. The light emitting element of claim 1, wherein the polarization inducing layer includes a metal material or a transparent conductive material.

13. The light emitting element of claim 1, further comprising a second insulating layer disposed to cover first and second surfaces of the polarization inducing layer.

14. The light emitting element of claim 13, wherein the first insulating layer includes an organic insulating material, and
wherein the second insulating layer includes an inorganic insulating material.

15. A display device comprising:
a substrate including a plurality of sub pixels, wherein the plurality of sub pixels include a plurality of light emitting elements, respectively;
a plurality of transistors on the substrate; and
a connection electrode connecting the plurality of transistors and the plurality of light emitting elements,
wherein each of the plurality of light emitting elements includes a polarization inducing layer, and
wherein the connection electrode is electrically connected to the plurality of light emitting elements on surfaces of the plurality of light emitting elements.

16. The display device of claim 15, wherein each of the plurality of light emitting elements further includes:
a first semiconductor layer;
a light emitting layer on the first semiconductor layer;
a second semiconductor layer on the light emitting layer;
a first electrode on the first semiconductor layer;
a second electrode on the second semiconductor layer;
a first insulating layer on the first electrode and the second electrode; and
a polarization inducing layer on the first insulating layer,
wherein the connection electrode is insulated from the polarization inducing layer.

17. The display device of claim 16, wherein each of the plurality of light emitting elements further includes a second insulating layer disposed on the polarization inducing layer, and
wherein the connection electrode covers a portion of a first surface of the second insulating layer.

18. The display device of claim 15, wherein the connection electrode is disposed on a same layer as the plurality of light emitting elements in an area excluding the plurality of light emitting elements.

19. A light emitting element comprising:
a first semiconductor layer having a plurality of first areas and a second area interposed between the plurality of first areas;
a light emitting layer on the first semiconductor layer;
a second semiconductor layer on the light emitting layer and overlapping with the second area of the first semiconductor layer;
a first electrode overlapping at least one of the plurality of first areas;
a second electrode overlapping the second area; and
a polarization inducing layer overlapping at least one of the plurality of first areas and not overlapping the second area.

20. The light emitting element of claim 19, further comprising an insulating layer overlapping the plurality of first areas and the second area, and interposed between the polarization inducing layer and the first and second electrodes.
